(19) United States
(12) Patent Application Publication
(10) Pub. No.: US 2025/0261520 A1
(43) Pub. Date: Aug. 14, 2025

(54) DISPLAY PANEL, DISPLAY DEVICE AND MASK

(71) Applicant: KunShan Go-Visionox Opto-Electronics Co., Ltd, Kunshan (CN)

(72) Inventors: Guobing HE, Kunshan (CN); Zhili MA, Kunshan (CN); Sheng GUO, Kunshan (CN)

(73) Assignee: KunShan Go-Visionox Opto-Electronics Co., Ltd, Kunshan (CN)

(21) Appl. No.: 19/193,878

(22) Filed: Apr. 29, 2025

Related U.S. Application Data
(63) Continuation of application No. PCT/CN2023/083863, filed on Mar. 24, 2023.

(30) Foreign Application Priority Data
Nov. 29, 2022 (CN) 202211507437.5

(51) Int. Cl. H10K 59/122; C23C 14/04; H10K 71/16

(52) U.S. Cl. CPC H10K 59/122; C23C 14/042; H10K 71/166

(57) ABSTRACT

Embodiments of the present application provide a display panel, a display device and a mask. The display panel includes: a substrate; a pixel defining layer, the pixel defining layer including an isolation portion and a plurality of pixel openings; and at least one support post arranged on a side of the isolation portion facing away from the substrate, the support post including a first section and a second section, an orthographic projection of at least part of the second section on the substrate being located within an orthographic projection of the first section on the substrate, where the isolation portion includes a first top surface distributed on a peripheral side of the first section, the first section includes a first side surface connected to the first top surface and extending toward the second section, and the first top surface intersects the first side surface.

### CROSS-REFERENCE TO RELATED APPLICATIONS

The application is a continuation application of International Application No. PCT/CN2023/083863, filed on Mar. 24, 2023, which claims priority to Chinese Patent Application No. 202211507437.5, entitled “DISPLAY PANEL, DISPLAY DEVICE AND MASK” and filed on Nov. 29, 2022, which is incorporated herein by reference in its entirety.

### FIELD

The present application relates to the field of display equipment, and particularly to a display panel, a display device and a mask.

### BACKGROUND

An organic light-emitting diode (OLED) is an active light-emitting device. Compared with a conventional liquid crystal display (LCD) method, an OLED display technology does not require a backlight and has a self-luminescence characteristic. The OLED uses a thin film layer of an organic material and a glass substrate. When a current passes through the film layer of the organic material, the organic material emits light. Therefore, an OLED display panel can significantly save power, can be made lighter and thinner, withstands a wider range of temperature changes than an LCD display panel, and has a larger viewing angle. The OLED display panel is expected to become the next generation of flat panel display technology after LCD, and is currently one of the flat panel display technologies that have attracted most attention.

The OLED display panel includes a pixel defining layer and at least one support post. The pixel defining layer includes an isolation portion and a plurality of pixel openings, and the support post is arranged on the isolation portion before a light-emitting material is evaporated in the pixel opening. During evaporation, scratching may occur between the support post and a mask for evaporating the light-emitting material, causing the support post to fall off, and accordingly the yield of the display panel is affected.

### SUMMARY

Embodiments of the present application provide a display panel, a display device and a mask, which are intended to improve the yield of the display panel.

An embodiment of the present application provides a display panel. The display panel has an active area and includes: a substrate; a pixel defining layer arranged on one side of the substrate, the pixel defining layer including an isolation portion and a plurality of pixel openings which are enclosed by the isolation portion and located in the active area; and at least one support post, at least one support post being located in the active area and arranged on a side of the isolation portion facing away from the substrate, the support post including a first section and a second section which are distributed in a stacked manner in a direction away from the isolation portion, an orthographic projection of at least part of the second section on the substrate being located within an orthographic projection of the first section on the substrate, where the isolation portion includes a first top surface distributed on a peripheral side of the first section, the first section includes a first side surface connected to the first top surface and extending toward the second section, and the first top surface intersects the first side surface.

An embodiment of the present application further provides a display device, including a display panel according to any one of the above embodiments.

An embodiment of the present application further provides a mask for fabricating a display panel, the display panel including a support post and a pixel defining layer. The mask includes:
a main mask area configured to fabricate the support post; and
a plurality of auxiliary openings configured to fabricate a first top surface of an isolation portion of the pixel defining layer, the plurality of auxiliary openings being arranged around a peripheral side of the main mask area, and at least two of the auxiliary openings being located on the same side of the main mask area in a first direction.

In the display panel provided in the embodiments of the present application, the display panel includes the substrate, and the pixel defining layer and the support post which are arranged on the substrate. The pixel defining layer includes the isolation portion and the pixel opening located in an active area, and a light-emitting unit may be arranged in the pixel opening to achieve display of the display panel. The support post is arranged on the isolation portion of the pixel defining layer, and the support post can assist in supporting a film layer such as a cover plate. A support post includes a first section and a second section, the isolation portion includes the first top surface distributed on the peripheral side of the first section, the first section and the pixel opening are spaced apart from each other due to the presence of the first top surface, and a spacing between the support post and the pixel opening can thus be increased, so that when particles are generated due to the fact that the support post is scratched, it is unlikely for the particles to fall into the pixel opening, and thus the yield of the display panel can be improved. The first section includes the first side surface connected to the first top surface, and the first top surface intersects the first side surface, so that the structural strength of the support post can be increased, and the problem of the support post being prone to damage due to scratching can be alleviated.

### BRIEF DESCRIPTION OF THE DRAWINGS

By reading the following detailed description made with reference to the drawings for non-limiting embodiments, the other features, objectives and advantages of the present application will become more apparent, in which the same or similar features are denoted by the same or similar reference numerals.

FIG. 1 is a cross-sectional view of a display panel according to an embodiment of the present application;

FIG. 2 is a structural schematic partial enlarged view of FIG. 1 in an example;

FIG. 3 is a structural schematic partial enlarged view of FIG. 1 in another example;

FIG. 4 is a structural schematic partial enlarged view of FIG. 1 in still another example;

FIG. 5 is a structural schematic partial enlarged view of FIG. 1 in yet another example;

FIG. 6 is a structural schematic partial enlarged view of FIG. 1 in still yet another example;

FIG. 7 is a structural schematic partial enlarged view of a display panel according to an embodiment of the present application;

FIG. 8 is a structural schematic view of a mask according to an embodiment of the present application;

FIG. 9 is a structural schematic partial enlarged view of FIG. 8 in an example;

FIG. 10 is a structural schematic view of a mask in a use state according to an embodiment of the present application;

FIG. 11 is a diagram of a product fabricated by a mask according to an embodiment of the present application;

FIG. 12 is a structural schematic partial enlarged view of FIG. 8 in another example;

FIG. 13 is a structural schematic partial enlarged view of FIG. 8 in still another example; and

FIG. 14 is a structural schematic partial enlarged view of FIG. 8 in yet another example.

### DESCRIPTION OF THE EMBODIMENTS

The features and exemplary embodiments of the present application in various embodiments will be described in detail below. In the following detailed description, many specific details are set forth to comprehensively understand the present application. However, it will be very apparent in the art that the present application may be implemented without some of these specific details. The following description of the embodiments are merely to provide a better understanding for the present application by illustrating examples of the present application. In the drawings and the following description, at least part of known structures and techniques are not shown to avoid unnecessary ambiguousness of the present application; and for the ease of clarity, the dimensions of part of the structure may be enlarged. In addition, the features, structures or characteristics described below may be combined, in any suitable manner, in one or more embodiments.

In the description of the present application, it should be noted that “a plurality of” means two or more, unless otherwise specified. The orientation or position relationship indicated by the terms “upper”, “lower”, “left”, “right”, “inner”, “outer”, etc. is only for the convenience of describing the present application and simplifying the description, rather than indicating or implying that the device or element referred to must have a particular orientation or be constructed and operated in a particular orientation, and therefore should not be construed as a limitation on the present application. Moreover, the terms such as “first” and “second” are merely used for the illustrative purpose, and should not be construed as indicating or implying the relative importance.

The orientation terms used in the following description all indicate directions shown in the accompanying drawings, and do not limit the specific structure of the embodiment of the present application. In the description of the present application, it should also be noted that unless otherwise explicitly specified and defined, the terms “mounting” and “connection” should be understood in a broad sense, for example, they may be a fixed connection, a detachable connection, or an integrated connection, and may be a direct connection, or an indirect connection. The specific meanings of the terms mentioned above in the present application can be construed according to specific circumstances.

A display panel actually produced in the related art includes a substrate and a pixel defining layer arranged on the substrate, the pixel defining layer including an isolation portion and a plurality of pixel openings, and a support post being arranged on a side of the isolation portion facing away from the substrate. After the support post is fabricated, a light-emitting material is evaporated in the pixel opening by using a mask. The inventors have found that during the alignment of the mask with the pixel opening, the mask may scratch the support post, arrange damage the support post, and thus generate impurities such as particles. When these impurities fall into the pixel opening, the light emission of the light-emitting material is affected seriously, and accordingly the yield of the display panel is reduced.

In view of this, the present application is provided. In order to better understand the present application, a display panel, a display device and a mask of the embodiments of the present application will be described in detail below with reference to FIGS. 1 to 14.

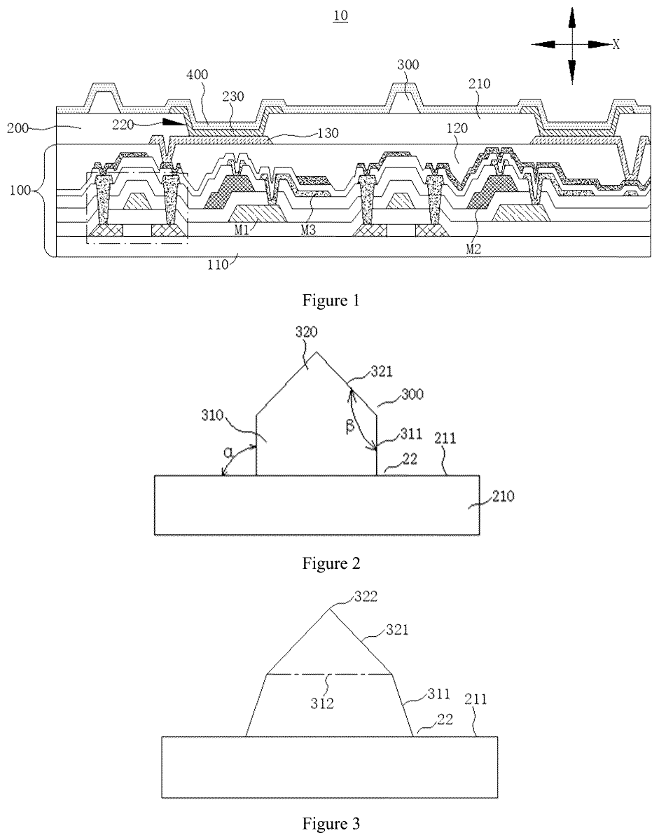

Referring to FIGS. 1 and 2, FIG. 1 is a cross-sectional view of a display panel 10 according to an embodiment of the present application, and FIG. 2 is a structural schematic partial enlarged view of FIG. 1 in an example.

As shown in FIGS. 1 and 2, the embodiment of the present application provides a display panel 10. The display panel 10 has an active area, and the display panel 10 includes a substrate 100, a pixel defining layer 200 and a support post 300. The pixel defining layer 200 is arranged on one side of the substrate 100, and the pixel defining layer 200 includes an isolation portion 210 and a plurality of pixel openings 220 which are enclosed by the isolation portion 210 and located in the active area. At least one support post 300 is located in the active area and arranged on a side of the isolation portion 210 facing away from the substrate 100. The support post 300 includes a first section 310 and a second section 320 which are distributed in a stacked manner in sequence in a direction away from the isolation portion 210. An orthographic projection of at least part of the second section 320 on the substrate 100 is located within an orthographic projection of the first section 310 on the substrate 100, the isolation portion 210 includes a first top surface 211 distributed on a peripheral side of the first section 310, and the first section 310 includes a first side surface 311 extending toward the second section 320.

In one embodiment, the entire orthographic projection of the second section 320 on the substrate 100 is located within the orthographic projection of the first section 310 on the substrate 100.

In one embodiment, the first section 310 of the support post 300 is partially exposed to form the first top surface 211 and the first side surface 311 as shown in FIGS. 2 to 6, thus forming a receiving space 22 for receiving impurities. That is, the first top surface 211 and the first side surface 311 are connected to each other in an intersecting manner, to form the receiving space 22 for receiving the impurities. As shown in FIGS. 2 to 5, connecting the first top surface 211 and the first side surface 311 in an intersecting manner includes: the first top surface 211 and the first side surface 311 being connected to each other in an intersecting manner with an included angle formed therebetween, and the first top surface 211 may be a flat surface or an arc-shaped surface shown in FIG. 5. Alternatively, connecting the first top surface 211 and the first side surface 311 in an intersecting manner includes, as shown in FIG. 6, the first top surface 211 and the first side surface 311 being smoothly connected to each other in an intersecting manner.

In the display panel 10 according to the embodiments of the present application, the display panel 10 includes the substrate 100, and the pixel defining layer 200 and the support post 300 which are arranged on the substrate 100. The pixel defining layer 200 includes the isolation portion 210 and the pixel opening 220 located in the active area, and a light-emitting unit 230 may be arranged in the pixel opening 220 to achieve display of the display panel 10. The support post 300 is arranged on the isolation portion 210 of the pixel defining layer 200, and the support post 300 can assist in supporting a film layer such as a cover plate. The support post includes the first section 310 and the second section 320. The isolation portion 210 includes the first top surface 211 distributed on the peripheral side of the first section 310, and the first section 310 and the pixel opening 220 are spaced apart from each other due to the presence of the first top surface 211, and a spacing between the support post 300 and the pixel opening 220 can thus be increased. When the impurities such as particles are generated due to the fact that the support post 300 is scratched, it is unlikely for the particulate impurities to fall into the pixel opening 220, and accordingly the yield of the display panel 10 can be improved. The first section 310 includes the first side surface 311 connected to the first top surface 211, and the first top surface 211 and the first side surface 311 intersect each other, or are smoothly connected to each other in such a manner that extending lines of the first top surface and the first side surface intersect each other, so that the structural strength of the support post 300 can be increased, and the problem of the support post 300 being prone to damage due to scratching can be alleviated.

The substrate 100 may be configured in a variety of forms. For example, the substrate 100 may be an array substrate, which may further include a pixel drive circuit. For example, the array substrate may include a base substrate 110, and a first conductive layer M1, a second conductive layer M2 and a third conductive layer M3 which are arranged in a stacked manner on one side of the base substrate 110. An insulating material layer is provided between adjacent conductive layers. By way of example, the pixel drive circuit arranged on the array substrate includes a transistor and a storage capacitor. The transistor includes a semiconductor, a gate, a source and a drain. The storage capacitor includes a first plate and a second plate. As an example, the gate and the first plate may be located in the first conductive layer M1, the second plate may be located in the second conductive layer M2, and the source and the drain may be located in the third conductive layer M3.

In one embodiment, the display panel 10 further includes a planarization layer 120 located on a side of the third conductive layer facing away from the base substrate 110, and a pixel electrode layer located on a side of the planarization layer 120 facing away from the base substrate 110. The pixel electrode layer includes a plurality of pixel electrodes 130 (also referred to as anodes or first electrodes) distributed at intervals. In one embodiment, the display panel 10 further includes a common electrode layer 400 (also referred to as a cathode layer or a second electrode layer) located on the side of the pixel defining layer 200 facing away from the substrate 100. The common electrode layer 400 and the pixel electrode 130 act together to drive the light-emitting unit 230 in the pixel opening 220 to emit light.

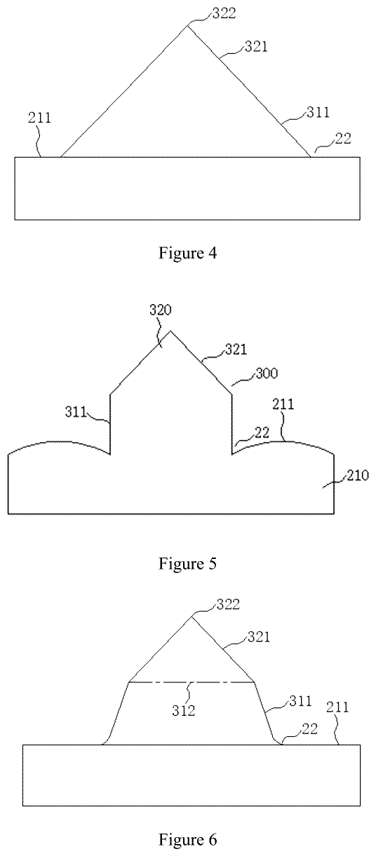

Referring to FIGS. 2 to 4 together, FIG. 3 is a structural schematic partial enlarged view of FIG. 1 in another example, and FIG. 4 is a structural schematic partial enlarged view of FIG. 1 in still another example.

In some embodiments, as shown in FIGS. 2 to 4, a first included angle a formed by the first side surface 311 and the first top surface 211 is greater than or equal to 90 degrees.

In these embodiments, when the first included angle a is greater than or equal to 90 degrees, a cross-section of the first section 310 is consistent or gradually decreases in a direction away from the substrate 100, so that the structural strength of the first section 310 can be increased, and the problem of the support post 300 being prone to damage due to scratching can be alleviated. The cross-section of the first section 310 is parallel to a surface where the substrate 100 is located.

In one embodiment, as shown in FIGS. 3 and 4, the first included angle is in the range of 130°-160°. In this way, the cross-section of the first section 310 gradually decreases in the direction away from the substrate 100, and the structural strength of the support post 300 can be further increased. The first included angle a is within the above-mentioned value range. For example, when the first included angle α is 130°, 140°, 150° or 160°, it is possible to alleviate the problem of insufficient extension height of the first section 310 in a thickness direction Z due to the excessively large first included angle α, affecting the support performance of the support post 300; and it is also possible to alleviate the problem of insufficient structural strength of the support post 300 due to the excessively small first included angle α.

Referring to FIG. 5, FIG. 5 is a structural schematic partial enlarged view of FIG. 1 in yet another example.

The first top surface 211 may be configured in a variety of forms. As shown in FIG. 5, for example, the first top surface 211 is shaped to protrude toward the support post 300.

In some embodiments, with continued reference to FIGS. 2 to 4, the first top surface 211 is a flat surface. Since the first top surface 211 is a flat surface rather than a recessed surface, it can be ensured that the isolation portion 210 has a sufficient thickness, the display problem caused by the short-circuit connection between the common electrode layer 400 and the pixel electrode is alleviated, and the yield of the display panel 10 can further be improved. In addition, since the first top surface 211 is flat surface, the flatness of a surface of the isolation portion 210 facing away from the substrate 100 can be improved, and the problem of wear particles being generated due to the uneven surface of the isolation portion 210 when the mask 500 scratches the isolation portion 210 during evaporation can be alleviated.

In one embodiment, with continued reference to FIGS. 2 to 4, the first top surface 211 is parallel to a plane where the substrate 100 is located. Generally, a surface of the planarization layer 120 facing the pixel defining layer 200 is parallel to the plane where the substrate 100 is located, the first top surface 211 is parallel to where the substrate 100 is located, and the first top surface 211 is thus parallel to the surface of the planarization layer 120 facing the pixel defining layer 200, such that the pixel defining layer 200 trends to be uniform in thickness at different positions.

In some embodiments, with continued reference to FIGS. 2 to 4, the cross-sectional area of the second section 320 gradually decreases in a direction from the first section 310 to the second section 320.

In these embodiments, since the cross-section of the second section 320 gradually decreases in the direction away from the substrate 100, the structural strength of the second section 320 can be increased, the structural strength of the support post 300 can thus be increased, and the support post 300 is less prone to damage or breakage when being scratched by the mask 500 during evaporation.

In one embodiment, the second section 320 includes a second top 322 and a second side surface 321 connecting the second top 322 and the first side surface 311, and the second side surface 321 is inclined toward the second top 322 in the direction from the first section 310 to the second section 320. The structural strength of the second section 320 can be increased, and the orthographic projection area of the second section 320 on the substrate 100 is less than or equal to the orthographic projection area of the first section 310 on the substrate 100, that is, the cross-sectional dimension of the second section 320 is less than or equal to the cross-sectional dimension of the first section 310, so that the first section 310 can provide sufficient support to second section 320, and the problem of the support post 300 being prone to damage due to the scratching can be better alleviated.

In some embodiments, the second section 320 is configured to be arranged centrosymmetrically with respect to the second top 322. The centrosymmetry herein does not mean symmetry in the geometric sense, as long as the second section 320 is arranged centrosymmetrically with respect to the second top 322 within a range of manufacturing errors.

In these embodiments, when the second section 320 is arranged centrosymmetrically with respect to the second top 322, the shape of the second section 320 is more regular, so that it is easier to fabricate and form the second section 320. In addition, the structure strength of the second section 320 can also tend to be consistent at the different positions, and when the mask 500 scratches the support post 300 in different directions, the second section 320 at the different positions is less prone to damage due to scratching to generate impurities such as the particles.

In one embodiment, the second section 320 may be in the shape of a cone, a truncated cone, or a polygonal pyramid. When the second section 320 is in the shape of a polygonal pyramid, the cross-section of the second section 320 is in the shape of a regular polygon, such that the second section 320 is arranged centrosymmetrically with respect to the second top 322.

In some embodiments, the first section 310 is arranged centrosymmetrically with respect to the second top 322. The centrosymmetry herein does not mean symmetry in the geometric sense, as long as the first section 310 is arranged centrosymmetrically with respect to the second top 322 within a range of manufacturing errors.

In these embodiments, when the first section 310 is arranged centrosymmetrically with respect to the second top 322, the shape of the first section 310 is more regular, so that it is easier to fabricate and form the first section 310. In addition, the structure strength of the first section 310 can also tend to be consistent at the different positions, and when the mask 500 scratches the support post 300 in different directions, the first section 310 at the different positions is less prone to damage due to scratching to generate impurities such as the particles.

In one embodiment, the first section 310 may be in the shape of a truncated cone or a truncated polygonal pyramid. When that first section 310 is in the shape of the truncated polygonal pyramid, the cross-section of the first section 310 is in the shape of a regular polygon, such that the first section 310 is arranged centrosymmetrically with respect to the second top 322.

In one embodiment, the cross-sectional shape of the first section 310 is identical to the cross-sectional shape of the second section 320. For example, the cross-sections of the first section 310 and the second section 320 may both be circular, such that the shape of the support post 300 is more regular. Alternatively, the cross-sections of the first section 310 and the second section 320 are both polygonal. In one embodiment, the sides of the cross-section of the first section 310 are configured to be parallel to the sides of the cross-section of the second section 320 to further simplify the shape and structure of the support post 300.

The first section 310 may be shaped in a variety of forms. In one embodiment, with continued reference to FIGS. 3 and 4, the cross-sectional area of the first section 310 gradually decreases in the direction from the first section 310 to the second section 320.

In these embodiments, the cross-sectional area of the first section 310 gradually decreases in the direction away from the substrate 100, and the first section 310 is of a structure having a larger top and a smaller bottom, so that the structural strength of the first section 310 can be increased, the structural strength of the support post 300 can be thus increased, and the problem of the support post 300 being prone to damage due to scratching can be alleviated.

In one embodiment, the orthographic projection of the second section 320 on the substrate 100 is located within the orthographic projection of the first section 310 on the substrate 100, so that the first section 310 can better support the second section 320, and the structural strength of the support post 300 can further be increased.

In one embodiment, the first section 310 has a first support surface 312 (schematically shown by a dotted line in FIG. 3) facing the second section 320, and the orthographic projection of the second section 320 on the substrate 100 completely overlaps with an orthographic projection of the first support surface 312 on the substrate 100, such that the second section 320 has a large enough dimension.

In some other embodiments, as shown in FIG. 2, the cross-sectional area of the first section 310 is constant in the direction from the first section 310 to the second section 320, that is, the first section 310 is configured to have a uniform cross-section, such that the first section 310 has a large enough area to support the second section 320, and the structural strength of the support post 300 can also be increased.

In one embodiment, an inner included angle ß between the second side surface 321 and the first side surface 311 is greater than 90 degrees and less than or equal to 180 degrees. In one embodiment, as shown in FIGS. 2 and 4, the inner included angle β between the second side surface 321 and the first side surface 311 is equal to 180 degrees, such that a surface of the support post 300 is smoother and is less likely to be scratched by the mask 500. For example, in the direction away from the substrate 100, the first side surface 311 and the second side surface 321 are coplanar and are both inclined toward the second top 322. Alternatively, as shown in FIGS. 2 and 3, the inner included angle β between the second side surface 321 and the first side surface 311 is greater than 90 degrees and less than 180 degrees, and an included angle between the second side surface 321 and the thickness direction Z is greater than an included angle between the first side surface 311 and the thickness direction Z, so that the structural strength of the second section 320 can further be increased, and the second section 320 located at the top end of the support post 300 is less prone to damage when being scratched by the mask 500.

In one embodiment, as shown in FIGS. 3 and 4, when the cross-sectional area of the first section 310 gradually decreases in the direction away from the substrate 100, the inner included angle β between the first side surface 311 and the second side surface 321 is greater than 90 degrees and less than or equal to 180 degrees. When the cross-sectional area of the first section 310 is constant in the direction away from the substrate 100, as shown in FIG. 2, the included angle β between the first side surface 311 and the second side surface 321 is greater than 90 degrees and less than 180 degrees. When the first section 310 is configured to have a uniform cross-section, the cross-section of the second section 320 gradually decreases in the direction away from the substrate 100 to increase the structural strength of second section 320.

In one embodiment, the extension dimension of the first top surface 211 in the peripheral direction of the first section 310 is greater than or equal to 1 μm, so that the problem is alleviated that the extension dimension of the first top surface 211 is excessively small, that is, the extension dimension of the first top surface 211 is greater than or equal to 1 μm in a direction radiating outward from the second top 322 to the pixel opening 220, resulting in the first section 310 and the pixel opening 220 being too close, and thus when the support post 300 is frictionally damaged to generate impurities such as particles, the impurities are prone to falling into the pixel opening 220.

In some embodiments, the extension height of the support post 300 in the thickness direction Z is in the range of 1.5-2.5 μm. When the height of the support post 300 is within the above value range, the problem of being unlikely to support a structural member such as the cover plate due to the insufficient height of the support post 300 can be alleviated, and the problem of the excessively large height of the support post 300 affecting the structural strength of the support post 300 and thus the support post 300 being prone to damage due to the scratching can also be alleviated.

In one embodiment, the extension height of the first section 310 in the thickness direction Z of the display panel 10 is in the range of 0.8-1.0 μm, and the extension height of the second section 320 in the thickness direction Z of the display panel 10 is in the range of 1.4-2.4 μm.

The support post 300 may be made of a variety of materials. For example, the material of the support post 300 is the same as the material of the pixel defining layer 200, so that the support post 300 and the pixel defining layer 200 can be fabricated and formed in the same process step, a fabrication process for the display panel 10 can be simplified, and the fabrication efficiency of the display panel 10 can be improved.

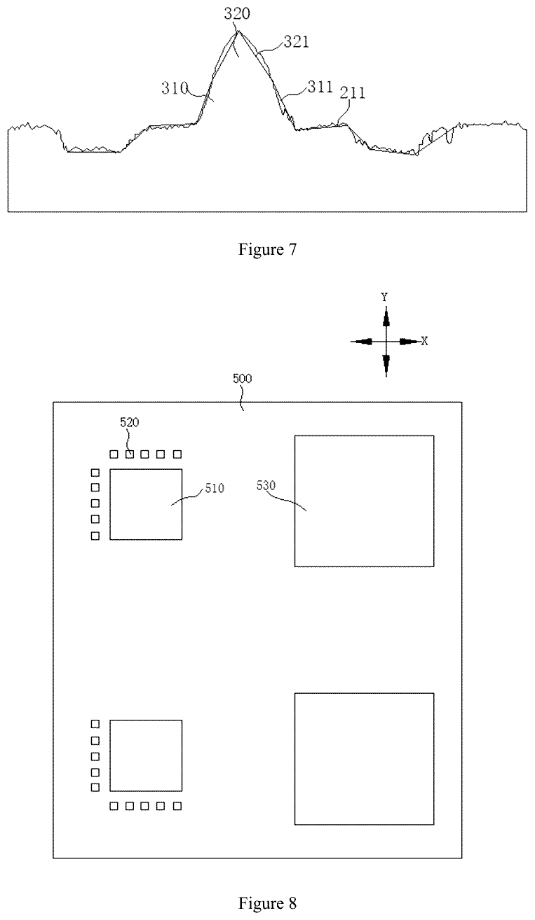

When the pixel defining layer 200 and the support post 300 are fabricated by using the mask, the first side surface 311, the second side surface 321 and the first top surface 211 formed may not be planes in the geometric sense due to the limitations of the process, and thus it is unlikely to present an included angle in the geometric sense. As shown in FIG. 7, within the range of process errors, it is enough that rough planes can be found to represent the first side surface 311, the second side surface 321 and the first top surface 211, and included angles between these planes can be determined.

An embodiment of the present application further provides a display device, including a display panel 10 of any one of the above embodiments. Since the display device according to the embodiment of the present application includes the display panel 10 of any one of the above embodiments, the display device according to the embodiment of the present application has the beneficial effects of the display panel 10 of any one of the above embodiments, and will not be described in detail here.

The display device in the embodiment of the present application includes, but is not limited to devices having a display function, such as a cell phone, a personal digital assistant (PDA), a tablet computer, an e-book, a television, an access control, a smart fixed-line telephone, or a control console.

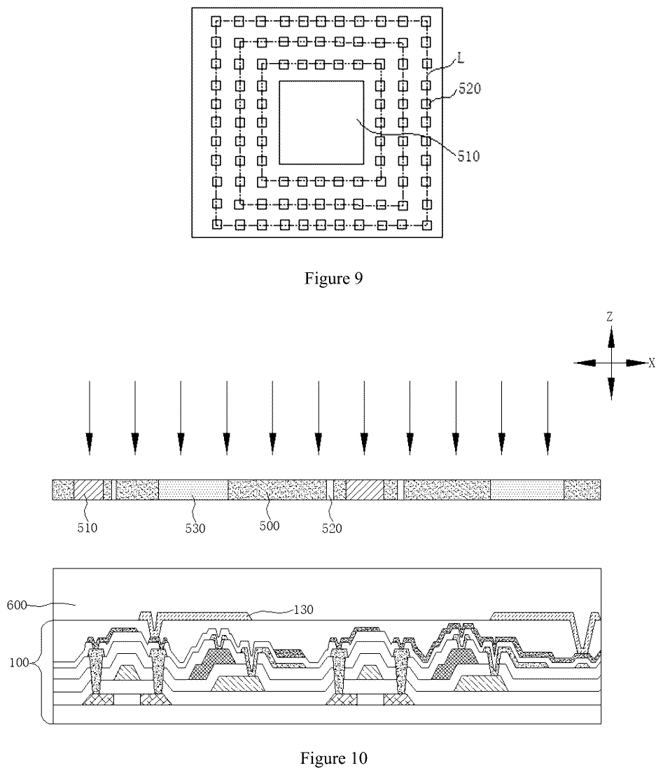

Referring to FIGS. 8 and 9, FIG. 8 is a structural schematic view of a mask 500 according to an embodiment of the present application, and FIG. 9 is a structural schematic partial enlarged view of FIG. 8 in an example. An embodiment of the present application further provides a mask 500, the mask 500 being configured to fabricate the support post 300 and the pixel defining layer 200 in any one of the above embodiments.

Referring to FIGS. 1 to 9 together, the mask 500 according to the embodiments of the present application includes a main mask area 510 and a plurality of auxiliary openings 520. The main mask area 510 is configured to fabricate the support post 300; and the auxiliary openings 520 are configured to fabricate the first top surface 211. The plurality of auxiliary openings 520 are arranged around a peripheral side of the main mask area 510, and at least two of the auxiliary openings 520 are located on the same side of the main mask area 510 in a first direction X. Referring to FIGS. 1 to 11 together, FIG. 10 is a structural schematic view of a mask 500 in a use state according to an embodiment of the present application, and FIG. 11 is a product fabricated by FIG. 10.

As shown in FIG. 10, when the mask 500 is configured to fabricate the display panel 10, it is possible that after the substrate 100 is coated with a functional material layer 600 for fabricating the pixel defining layer 200 of the support post 300, the mask 500 is arranged on a side of the functional material layer 600 facing away from the substrate 100, and a side of the mask 500 facing away from the functional material layer 600 is then irradiated with laser, enabling the laser to pattern the functional material layer 600. As shown in FIG. 11, a part of the functional material layer 600 corresponding to the main mask area 510 can form the support post 300, and a part of the functional material layer 600 corresponding to the auxiliary opening 520 can form the first top surface 211. FIG. 10 shows an incidence direction of the laser with arrows.

In one embodiment, two or more auxiliary openings 520 are arranged in a column at equal intervals on the same side of the main mask area 510.

In the mask 500 according to the embodiment of the present application, the plurality of auxiliary openings 520 are arranged around the peripheral side of the main mask area 510. At least two of the auxiliary openings 520 are located on the same side of the main mask area 510 in the first direction X, that is, two or more auxiliary openings 520 are arranged at intervals on the same side of the main mask area 510, the laser cannot pass through a region between two adjacent auxiliary openings 520, but the laser can be irradiated to the functional material layer 600 through the auxiliary openings 520, thus forming the first top surface 211 and the first side surface 311 which can constitute the receiving space 22 for receiving the impurities. Compared with a solution in which an elongated opening is formed on the same side of the main mask area 510, the smaller-sized auxiliary openings 520 can allow a decrease in the amount of laser irradiated to the functional material layer 600, thereby alleviating the problem of the breakdown of the functional material layer 600 caused by the excessive amount of laser, and the resulting short-circuit connection between the common electrode layer 400 and the pixel electrode 130. Compared with a solution in which no openings are formed in the peripheral side portions of the main mask area 510, by providing the auxiliary openings 520, the first top surface 211 can be formed for receiving the particles generated by scratching, thereby alleviating the problem of the particles generated when the support post 300 is scratched being likely to enter the pixel opening 220 due to the relatively small distance between the support post 300 and the pixel openings 220, and thus affecting the evaporation yield of a subsequent process procedure.

Therefore, in the mask 500 according to the embodiment of the present application, by providing at least two auxiliary openings 520 distributed at intervals on the same side of the main mask area 510, it is not only possible to alleviate the problem of the breakdown of the functional material layer 600 caused by the excessive amount of laser, and it is also possible to alleviate the problem of the excessively small distance between the fabricated support post 300 and the pixel opening 220.

In one embodiment, the plurality of auxiliary openings 520 are distributed in a grid pattern, such that the laser can better pass through the plurality of auxiliary openings 520, to form the first top surface 211 as described above.

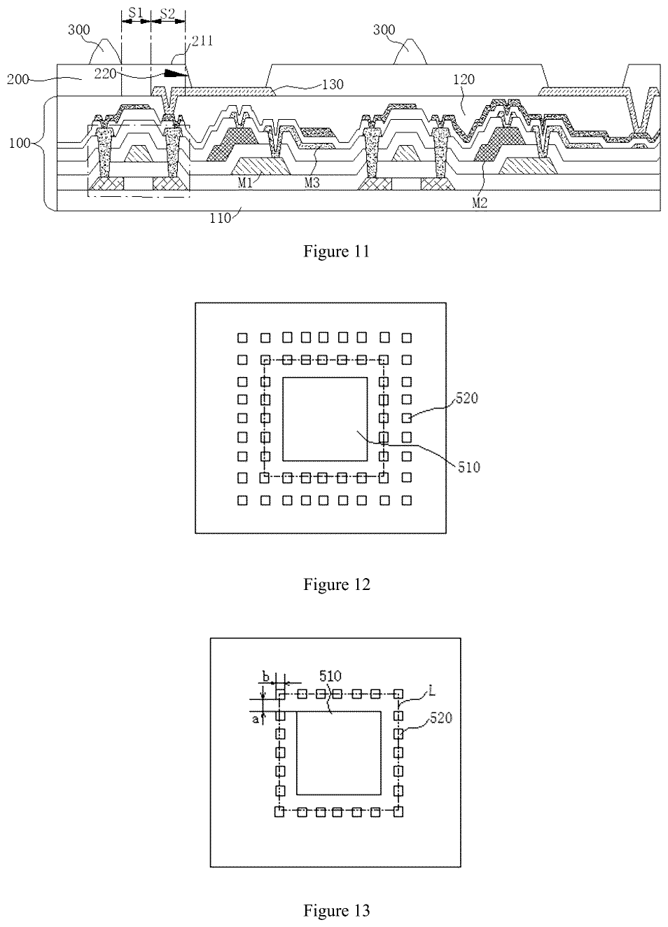

Referring to FIGS. 9, 12 and 13 together, FIG. 12 is a structural schematic partial enlarged view of FIG. 8 in another example, and FIG. 13 is a structural schematic partial enlarged view of FIG. 8 in still another example.

In some embodiments, as shown in FIGS. 9, 12 and 13, the plurality of auxiliary openings 520 are distributed at intervals along an annular path L surrounding the main mask area 510. The number of annular paths L is N, where N is less than or equal to 3.

The annular path L is a virtual path, and the annular path L does not limit the structure of the mask 500, but merely functions as a reference that is set for more conveniently describing a distribution pattern of the plurality of auxiliary openings 520. In one embodiment, the annular path L is in the shape of a closed annulus around the main mask area 510, and when N is greater than or equal to 2, the plurality of annular paths L are nested with each other.

In these embodiments, N is less than or equal to 3, that is, the number of annular paths L is relatively small, and the number of auxiliary openings 520 arranged on the same side of the main mask area 510 side by side in a direction from the main mask area 510 to the auxiliary openings 520 is relatively small. It is possible to alleviate the problem of the breakdown of the functional material layer 600 due to the fact that an excessive number of auxiliary openings 520 causes an excessive amount of laser to be irradiated to the functional material layer 600 during use of the mask 500. Moreover, when N is relatively small, by properly setting the positions of the auxiliary openings 520, it is also possible to decrease the maximum distance between the auxiliary opening 520 and the main mask area 510, thus reducing the influence of the auxiliary opening 520 on the shaping of the pixel opening 220.

In one embodiment, as shown in FIG. 11, N=1. That is, the plurality of auxiliary openings 520 are formed on the peripheral side of the main mask area 510, and the auxiliary openings 520 are distributed at intervals in a single-row manner around the main mask area 510, so that the distance between the auxiliary opening 520 and the main mask area 510 can be reasonably controlled, and the structure of the mask 500 can be simplified.

In one embodiment, the auxiliary opening 520 may be shaped in a variety of forms. For example, the auxiliary opening 520 is in a circular or polygonal shape, so that the auxiliary opening 520 is more regular in shape and can be easily fabricated and formed. For example, the auxiliary opening 520 may be in a circular, square, rectangular, or zigzag shape.

In one embodiment, the auxiliary opening 520 has a maximum width b of 1-2 μm. When the maximum width of the auxiliary opening 520 is within the above value range, it is possible to alleviate the problem of the failure of the formation of the first top surface 211 caused by insufficient amount of laser due to the excessively small size of the auxiliary opening 520, and it is also possible to alleviate the problem of the breakdown of the functional material layer 600 caused by excessive amount of laser due to the excessively large size of the auxiliary opening 520.

In one embodiment, the maximum width b of the auxiliary opening 520 may be the extension dimension of the auxiliary opening 520 in any direction on the plane where the surface of the mask 500 is located. For example, the maximum width of the auxiliary opening 520 may be the extension dimension of the auxiliary opening 520 in the first direction X or in a second direction Y.

In one embodiment, a minimum distance a between the auxiliary opening 520 and the main mask area 510 is greater than 0 and less than or equal to 2 μm. When the minimum distance a between the auxiliary opening 520 and the main mask area 510 is within the above value range, it is possible to reduce the influence of the excessively large minimum distance a between the auxiliary opening 520 and the main mask area 510 on the fabrication of the first top surface 211, and it is also possible to reduce the influence of the auxiliary opening 520 on the formation of the pixel opening 220.

In one embodiment, the mask 500 further includes a pixel opening formation area 530. The pixel opening formation area 530 is configured to form the pixel opening 220. In one embodiment, the auxiliary opening 520 is located between the pixel opening formation area 530 and the main mask area 510.

In some embodiments, the auxiliary openings 520 distributed at intervals along the same annular path L are arranged equidistant from an edge of the main mask area 510. The distances between the plurality of auxiliary openings 520 and the main mask area 510 trend to be consistent to form the first top surface 211 surrounding the peripheral side of the first section 310, so that the dimensions of the first top surface 211 at different positions in the peripheral direction of the first section 310 trend to be uniform.

In one embodiment, the auxiliary openings 520 on two sides of the main mask area 510 in the first direction X are the same in number, such that in the display panel 10 fabricated by using the mask 500, the distribution areas of the first top surface 211 on two sides of the support posts 300 in the first direction X trend to be consistent.

In one embodiment, the auxiliary openings 520 on two sides of the main mask area 510 in the second direction Y are the same in number, such that in the display panel 10 fabricated by using the mask 500, the distribution areas of the first top surface 211 on two sides of the support posts 300 in the second direction Y trend to be consistent.

As shown in FIGS. 9, 12 and 13, when the main mask area 510 is in a square shape, the auxiliary openings 520 on the two sides of the main mask area 510 in the first direction X are the same in number, the auxiliary openings 520 on the two sides of the main mask area 510 in the second direction Y are the same in number, and the number of auxiliary openings 520 located on one side of the main mask area 510 in the first direction X is the same as the number of auxiliary openings 520 located on one side of the main mask area 510 in the second direction Y. In this way, in the display panel 10 fabricated by using the mask 500, the distribution areas of the first top surface 211 on the two sides of the support post 300 in the first direction X and the second direction Y trend to be consistent.

In one embodiment, when the main mask area 510 is in a circular shape, the plurality of auxiliary openings 520 are arranged at equal intervals on the peripheral side of the main mask area 510. In this way, in the display panel 10 fabricated by using the mask 500, the distribution areas of the first top surface 211 at different positions of the support post 300 in the peripheral direction trend to be consistent.

In the display panel 10, the display panel 10 includes an array substrate in which a plurality of metal layers are provided, a pixel electrode 130 is also provided on a side of the array substrate facing the pixel defining layer 200, these metal layers and the pixel electrode 130 may reflect the laser, resulting in an excessive amount of laser in their corresponding regions, and thus affecting the shapes of the pixel defining layer 200 and the support post 300 formed.

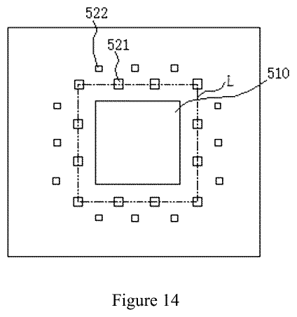

Referring to FIGS. 8 to 14 together, FIG. 14 is a structural schematic partial enlarged view of FIG. 8 in yet another example.

In some embodiments, the auxiliary openings 520 include a plurality of first auxiliary openings 521 and a plurality of second auxiliary openings 522. The first auxiliary opening 521 is configured to fabricate a first region S1 of the first top surface 211, and the second auxiliary opening 522 is configured to fabricate a second region S2 of the first top surface 211. The first region S1 is misaligned with a reflecting portion of the display panel 10 in the thickness direction Z of the display panel, the second region S2 at least partially overlaps with the reflecting portion in the thickness direction Z, and the area of the second auxiliary opening 522 is less than the area of the first auxiliary opening 521.

In these embodiments, as shown in FIG. 11, the first top surface 211 includes the first region S1 and the second region S2. Since the first region S1 is misaligned with the reflecting portion of the display panel 10 in the thickness direction Z, it is unlikely for the laser reflected by the reflecting portion to enter the first region S1. Since the second region S2 at least partially overlaps with the reflecting portion in the thickness direction Z, the laser reflected by the reflecting portion can easily enter the second region S2, resulting in an excessive amount of laser in the second region S2. In the embodiments of the present application, the area of the second auxiliary opening 522 for forming the second region S2 by means of evaporation is less than the area of the first auxiliary opening 521, so that the problem of the breakdown of the functional material layer 600 caused by the excessive amount of laser in the second region S2, and the resulting short-circuit connection between the common electrode layer 400 and the pixel electrode 130 can be alleviated.

The reflecting portion may be configured in a variety of forms, and a wire, the pixel electrode 130, etc. in the display panel 10 that has a reflecting function may be considered as the reflecting portion. In one embodiment, as shown in FIG. 11, the reflecting portion is the pixel electrode 130. A distance between the pixel electrode 130 and the pixel defining layer 200 is relatively small, and thus the reflection of the laser by the pixel electrode 130 is prone to affecting the formation of the pixel defining layer and the support post 300. By setting the second auxiliary opening 522 for evaporation of the second region S2 to be relatively small, the problem caused by the excessive amount of laser due to laser reflection by the pixel electrode 130 can be alleviated.

In one embodiment, the first auxiliary opening 521 is closer to the main mask area 510 than the second auxiliary opening 522. A distance between the reflecting portion (e.g., the pixel electrode 130) in the display panel and the pixel opening 220 is smaller than a distance between the pixel electrode 130 and the support post 300. By making the first auxiliary opening 521 closer to the main mask area 510 than the second auxiliary opening 522, the second auxiliary opening 522 is closer to the pixel electrode 130, so that the first auxiliary opening 521 being closer to the main mask area 510 than the second auxiliary opening 522 can be better improved, and the problem caused by the excessive amount of laser due to laser reflection by the pixel electrode 130 can be alleviated.

Although the present application is described with reference to some embodiments, various modifications can be made, and equivalents can be provided to substitute for the components thereof without departing from the scope of the present application. In particular, the features mentioned in the embodiments can be combined in any manner, provided that there is no structural conflict. The present application is not limited to the specific embodiments disclosed herein but includes all the embodiments that fall within the scope of the claims.

1. A display panel having an active area, the display panel comprising:
a substrate;
a pixel defining layer arranged on one side of the substrate, the pixel defining layer comprising an isolation portion and a plurality of pixel openings which are enclosed by the isolation portion and located in the active area; and
at least one support post, the at least one support post being located in the active area and arranged on a side of the isolation portion facing away from the substrate,
the support post comprising a first section and a second section which are distributed in a stacked manner in a direction away from the isolation portion, an orthographic projection of at least part of the second section on the substrate being located within an orthographic projection of the first section on the substrate,
wherein the isolation portion comprises a first top surface distributed on a peripheral side of the first section, the first section comprises a first side surface connected to the first top surface and extending toward the second section, and the first top surface intersects the first side surface.

2. The display panel according to claim 1, wherein a first included angle is formed between the first side surface and the first top surface, the first included angle being greater than or equal to 90 degrees.

3. The display panel according to claim 2, wherein the first included angle is in a range of 90-130 degrees.

4. The display panel according to claim 1, wherein the first top surface is a flat surface.

5. The display panel according to claim 1, wherein the first top surface is a protruding surface, and a first included angle is formed between the first side surface and the first top surface, the first included angle being less than 90 degrees.

6. The display panel according to claim 1, wherein the first side surface and the first top surface are smoothly connected to each other.

7. The display panel according to claim 1, wherein the second section comprises a second top, and a second side surface connecting the second top and the first side surface, a cross-sectional area of the second section gradually decreases in a direction from the first section to the second section, and the second side surface is inclined toward the second top.

8. The display panel according to claim 7, wherein the second section is arranged centrosymmetrically with respect to the second top;
and the first section is arranged centrosymmetrically with respect to the second top.

9. The display panel according to claim 7, wherein a cross-sectional area of the first section gradually decreases or is constant in the direction from the first section to the second section, and
an inner included angle between the second side surface and the first side surface is greater than 90 degrees and less than or equal to 180 degrees.

10. The display panel according to claim 1, wherein an extension dimension of the first top surface in a peripheral direction of the first section is greater than or equal to 1 μm;
and an extension height of the support post in a thickness direction of the display panel is in a range of 1.5-2.5 μm.

11. The display panel according to claim 1, wherein an extension height of the first section in a thickness direction of the display panel is in a range of 0.8-1.0 μm;
and an extension height of the second section in the thickness direction of the display panel is in a range of 1.4-2.4 μm.

12. A display device, comprising a display panel according to any one of claims 1.

13. A mask for fabricating a display panel, the display panel comprising at least one support post and a pixel defining layer, the mask comprising:
a main mask area configured to fabricate the support post; and
a plurality of auxiliary openings configured to fabricate a first top surface of an isolation portion of the pixel defining layer, the plurality of auxiliary openings being arranged around a peripheral side of the main mask area, and at least two of the auxiliary openings being located on the same side of the main mask area in a first direction.

14. The mask according to claim 13, wherein the plurality of auxiliary openings are distributed at intervals along at least one annular path surrounding the main mask area, a number of annular paths being N, where N is less than or equal to 3.

15. The mask according to claim 14, wherein N=1.

16. The mask according to claim 14, wherein a maximum width b of the auxiliary opening is in a range of 1-2 μm;
and a minimum distance a between the auxiliary opening and the main mask area is greater than 0 and less than or equal to 2 μm.

17. The mask according to claim 14, wherein the plurality of auxiliary openings distributed at intervals along the same annular path are arranged equidistant from an edge of the main mask area.

18. The mask according to claim 17, wherein the auxiliary openings on two sides of the main mask area in the first direction are the same in number;
and the auxiliary openings on two sides of the main mask area in a second direction are the same in number.

19. The mask according to claim 13, wherein the auxiliary openings comprise:
a plurality of first auxiliary openings configured to fabricate a first region of the first top surface, and
a plurality of second auxiliary openings configured to fabricate a second region of the first top surface, wherein the first region is misaligned with a reflecting portion of the display panel in a thickness direction of the display panel, the second region at least partially overlaps with the reflecting portion in the thickness direction, and an area of the second auxiliary opening is less than an area of the first auxiliary opening.

20. The mask according to claim 19, wherein the first auxiliary opening is closer to the main mask area than the second auxiliary opening.
